(19) United States
(12) Patent Application Publication
(10) Pub. No.: US 2025/0158631 A1
(43) Pub. Date: May 15, 2025

(54) METHODS AND SYSTEMS OF UTILIZING ANALOG-TO-DIGITAL CONVERTER (ADC) FOR MULTIPLY-ACCUMULATOR (MAC)

(71) Applicants: Vishal Sarin, saratoga, CA (US); Biprangshu Saha, bangalore (IN); Sankha Saha, santa clara, CA (US); Sang T. Nguyen, SAMMAMISH, CA (US); Vikram Kowshik, cupertino, CA (US); Siraj Moussa, sacramento, CA (US)

(72) Inventors: Vishal Sarin, saratoga, CA (US); Biprangshu Saha, bangalore (IN); Sankha Saha, santa clara, CA (US); Sang T. Nguyen, SAMMAMISH, CA (US); Vikram Kowshik, cupertino, CA (US); Siraj Moussa, sacramento, CA (US)

(21) Appl. No.: 18/414,882

(22) Filed: Jan. 17, 2024

Related U.S. Application Data
(63) Continuation-in-part of application No. 17/882,325, filed on Aug. 5, 2022.
Application No. 17/882,325 is a continuation-in-part of application No. 16/452,308, filed on Jun. 25, 2019, now Pat. No. 12,136,028.
(60) Provisional application No. 62/689,839, filed on Jun. 26, 2018.
(60) Provisional application No. 62/721,116, filed on Aug. 22, 2018.
(60) Provisional application No. 62/773,773, filed on Nov. 30, 2018.

(51) Int. Cl. H03M 1/36; H03M 1/12

(52) U.S. Cl. CPC H03M 1/36; H03M 1/1255

(57) ABSTRACT

The patent presents method of implementing a large number of ADC's in column pitch of array using a charge accumulation and measurement method on each bit line. The method uses a common voltage ramp node across ADC's with individual ADC floating node sensing so as to reduce power consumption while maintaining ADC accuracy. Systematic errors between program verify mode and MAC inference mode between accumulation and sense are eliminated inherently.

### CLAIM OF PRIORITY

This application is a continuation in part of U.S. patent application Ser. No. 17/882,325, filed on Aug. 5, 2022 and titled METHODS AND SYSTEMS OF OPERATING A NEURAL CIRCUIT IN A NON-VOLATILE MEMORY BASED NEURAL-ARRAY. This application is incorporated by reference in its entirety.

U.S. patent application Ser. No. 17/882,325 is a continuation in part of U.S. patent application Ser. No. 16/452,308, filed on Jun. 25, 2019 and titled METHODS AND SYSTEMS OF OPERATING A NEURAL CIRCUIT IN A NON-VOLATILE MEMORY BASED NEURAL-ARRAY. This application is incorporated by reference in its entirety.

U.S. patent application Ser. No. 16/452,308 claims priority to U.S. Provisional Application No. 62/689,839, filed on Jun. 26, 2018 and titled FORMING NEURONS WITH USING SLC FLASH CELLS. This provisional application is incorporated by reference in its entirety.

U.S. patent application Ser. No. 16/452,308 claims priority to U.S. Provisional Application No. 62/721,116, filed on Aug. 22, 2018 and titled METHODS AND SYSTEMS OF NEURAL-ARRAY BASED FLASH MEMORY. This provisional application is incorporated by reference in its entirety.

U.S. patent application Ser. No. 16/452,308 claims priority to U.S. Provisional Application No. 62/773,773, filed on Nov. 30, 2018 and titled FORMING NEURONS WITH USING SLC FLASH CELLS. This provisional application is incorporated by reference in its entirety.

### BACKGROUND

### 1. Field

This application generally relates to electronic circuits and, more particularly, to a system, method, and article of manufacture of utilizing analog to digital converter (ADC) for an Analog Multiplier-and-Accumulation system.

Analog MAC consists of several Analog Multiplier units that produce charges and are denoted by currents over a specific time q=i*t. The present invention relates to the ADC system with the accumulation unit that accumulates charges produced by each multiplier and then converts them to a digital value.

### 2. Related Art

Several ADC schemes were invented in the past that were suitable for different applications. Specific ADC implementations have used charge measurement methods using integrators and comparators. These ADCs have inherent limitations in size and accuracy when implemented for applications requiring thousands of ADCs to fit into tight memory array bit-line pitches. Furthermore, there are considerations on ADC accuracy when similar circuits are duplicated, due to device mismatch effects.

Power consumption becomes very high due to the duplication of circuits on multiple ADCs for in-memory-compute applications. Also, high voltage is required to provide enough headroom for the circuits in traditional implementations. This causes the overall power consumption to be untenable when thousands of ADCs are required to be used.

### SUMMARY OF THE INVENTION

In one aspect, an analog-to-digital converter (ADC) system comprising: a complementary metal-oxide-semiconductor (CMOS) circuit configured to receive a charge as an input charge that is converted to a digital value; a capacitor configured to store the input charge and develop a voltage across the capacitor that is proportional to the input charge; a CMOS pre-charge circuit configured to pre-charge the capacitor to a reference voltage (Vref); a top plate of the capacitor that is initially held to the Vref while a bottom plate is tied to a circuit ground or an alternative fixed voltage, wherein during a charge accumulation phase, a voltage across the capacitor starts with Vref and ends at a different value based on an input or an accumulated charge; a CMOS transistor configured to connect and disconnect the bottom plate of the capacitor during a charge accumulation phase and a resolution phase; a CMOS voltage level comparator configured to monitor a capacitor ramp in the resolution phase and to detect when a capacitor ramp reaches a predefined voltage level; a synchronizer circuit configured to synchronize the asynchronous comparator output signal of the CMOS the comparator with a clock; a pulse generator configured to receive the signal from synchronizer and generate a pulse signal; and an N-bit D-latch configured to latch the counter data using the pulse from the pulse generator to produce the N-bit ADC output. Using a common electrical node, and consequently, a common circuit ramp method for all the ADCs during resolution ensures the required consistency in ADC output across all the ADC's for analog in-memory compute implementations.

### BRIEF DESCRIPTION OF THE DRAWINGS

FIG. 1-A schematically shows an example ADC system with an accumulator unit and reference slope insertion at the bottom plate of the ADC capacitor, according to some embodiments.

FIG. 1-B schematically shows an example ADC control unit with a reference slope generation circuit, according to some embodiments.

FIG. 1-C schematically shows an example circuit system that helps to generate a best ADC output for an out-of-the-range input, according to some embodiments.

FIG. 1-D shows an example waveform and signal flow diagram for the ADC system of FIGS. 1-A to C, according to some embodiments.

FIG. 1-E shows an example of a multi-ADC system 172, according to some embodiments.

FIG. 2-A shows an alternate example ADC system and control unit that depicts the mechanism of reference slope generation by directly charging the ADC capacitor with a reference current source, according to some embodiments.

FIG. 2-B shows an example waveform for the system of FIG. 2-A, according to some embodiments.

The Figures described above are a representative set and are not exhaustive with respect to embodying the invention.

### DESCRIPTION

Disclosed are a system, method, and article of manufacture for utilizing analog accumulators and analog to digital converter (ADC) for Analog multiply-accumulator (MAC).

The following description is presented to enable a person of ordinary skill in the art to make and use the various embodiments. Descriptions of specific devices, techniques, and applications are provided only as examples. Various modifications to the examples described herein can be readily apparent to those of ordinary skill in the art, and the general principles defined herein may be applied to other examples and applications without departing from the spirit and scope of the various embodiments.

Reference throughout this specification to ‘one embodiment,’ ‘an embodiment,’ ‘one example,’ or similar language means that a particular feature, structure, or characteristic described in connection with the embodiment is included in at least one embodiment of the present invention. Thus, appearances of the phrases ‘in one embodiment,’ ‘in an embodiment,’ and similar language throughout this specification may, but do not necessarily, all refer to the same embodiment.

Furthermore, the described features, structures, or characteristics of the invention may be combined in any suitable manner in one or more embodiments. In the following description, numerous specific details are provided, such as examples of programming, software modules, user selections, network transactions, database queries, database structures, hardware modules, hardware circuits, hardware chips, etc., to provide a thorough understanding of the embodiments of the invention. One skilled in the relevant art can recognize, however, that the invention may be practiced without one or more of the specific details, or with other methods, components, materials, and so forth. In other instances, well-known structures, materials, or operations are not shown or described in detail to avoid obscuring aspects of the invention.

The schematic flow chart diagrams included herein are generally set forth as logical flow chart diagrams. As such, the depicted order and labeled steps are indicative of one embodiment of the presented method. Other steps and methods may be conceived that are equivalent in function, logic, or effect to one or more steps, or portions thereof, of the illustrated method. Additionally, the format and symbols employed are provided to explain the logical steps of the method and are understood not to limit the scope of the method. Although various arrow types and line types may be employed in the flow chart diagrams, they are understood not to limit the scope of the corresponding method. Indeed, some arrows or other connectors may be used to indicate only the logical flow of the method. For instance, an arrow may indicate a waiting or monitoring period of unspecified duration between enumerated steps of the depicted method. Additionally, the order in which a particular method occurs may or may not strictly adhere to the order of the corresponding steps shown.

### Definitions

Example definitions for some embodiments are now provided.

Analog-to-digital converter (ADC) is a system that converts an analog signal level to its digital value defined by a set of digital signals.

The current mirror can be a circuit designed to copy a current through one active device by controlling the current in another active device of a circuit, keeping the output current constant regardless of loading.

An integrator can be an element whose output signal is the time integral of its input signal. It can accumulate the input quantity over a defined time to produce a representative output.

An analog Multiply-accumulator (MAC) is an analog compute block which computes products of two numbers and accumulates the product outputs in the analog domain. An analog MAC system is often followed by an ADC to interface with the following digital system.

GND refers to the universal Ground connection in electrical engineering. It is the reference point and represents a Zero potential for the entire circuit under discussion.

An operational amplifier (herein ‘op-amp’) can be a DC-coupled high-gain electronic voltage amplifier with a differential input and an n-ended output (e.g., a single-ended output).

A parasitic element is a circuit element that is possessed by an electrical component, but which is not desirable for it to have for its intended purpose.

### Example Computer Architecture and Systems

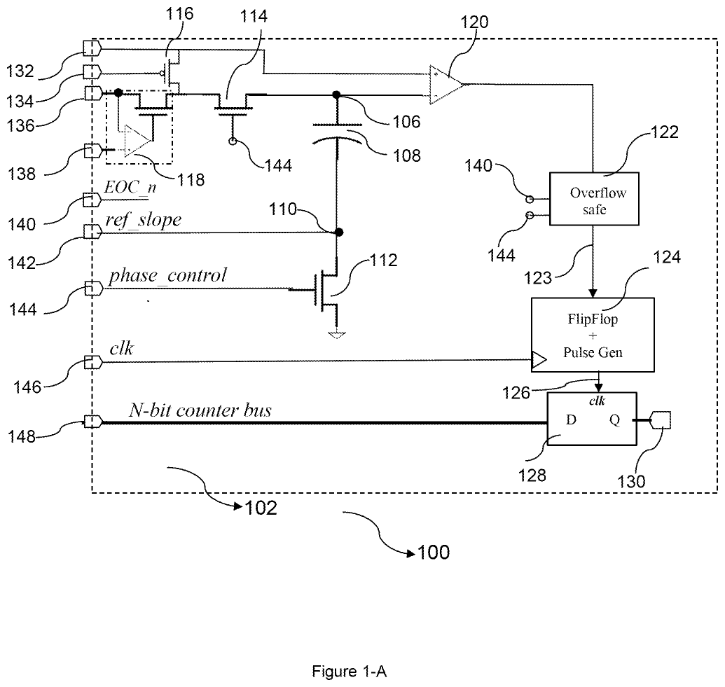

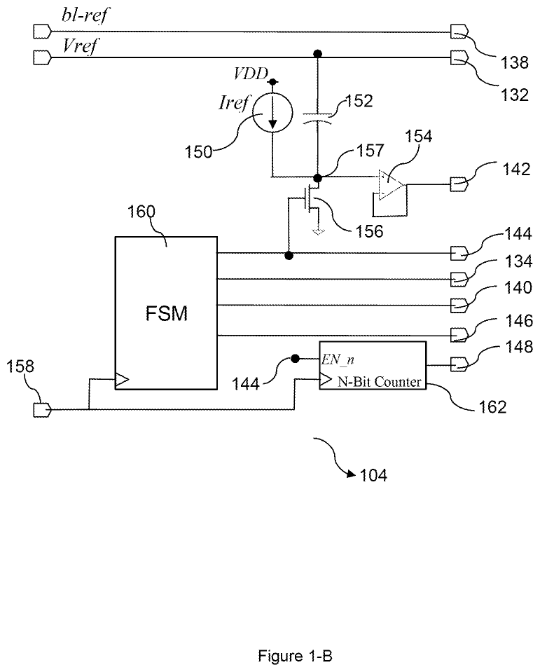

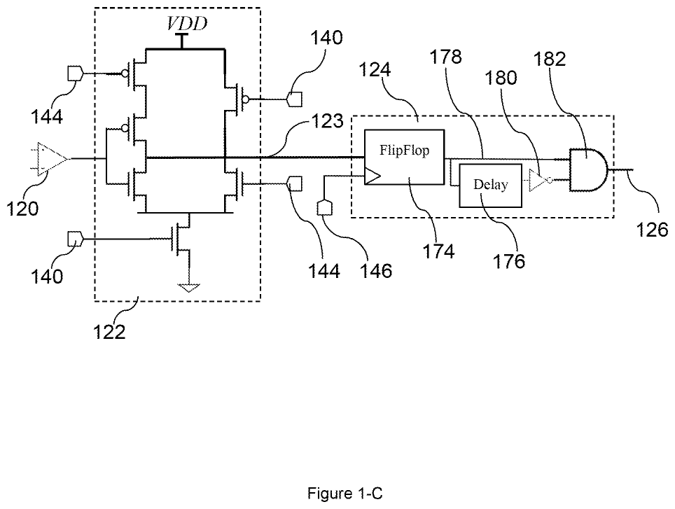

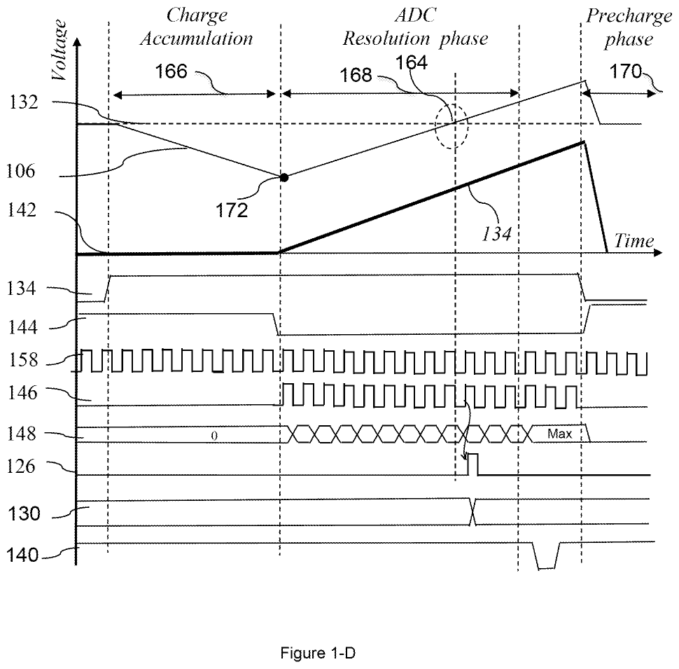

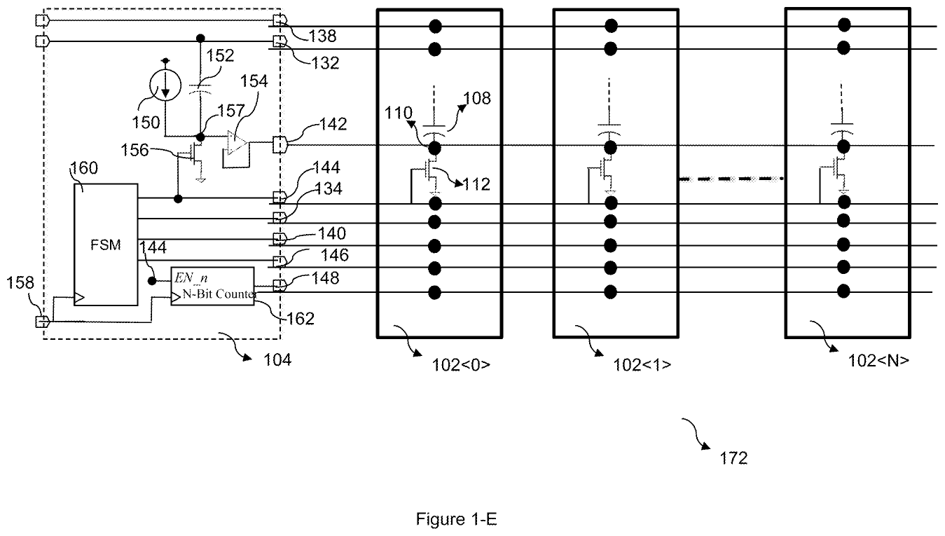

FIGS. 1-A to D illustrate ADC system 100 with ADC 102 and ADC control 104, according to some embodiments. The ADC 102 employs a capacitor 108 connected between two nodes: Sense node 106 and reference slope insertion node 110, which are top and bottom plates of the capacitor 108 respectively. The ADC 102 operates in two phases. First, the charge accumulation takes place at capacitor 108, and then the corresponding developed capacitor voltage at the sense node 106 is converted to a digital value in the resolution phase. Several circuits and methods were innovated and implemented to achieve the ADC conversion efficiently.

The ADC 102 receives the input on port 136, which connects to subsystem 118, consisting of an op-amp and transistor. Circuit system 118 enables the input charge on port 136, composed of currents over certain time windows, to accumulate in the capacitor 108.

Hence, the developed voltage across the capacitor is proportional to the input charge. The ADC performs “accumulation” for the analog MAC (Multiply and Accumulation) operation through the circuit system 118. Circuit 118 receives a reference voltage “bl_ref” 138, which it maintains at the input port 136 to facilitate the preceding multiplier system, which is connected at port 136, to develop currents at a constant voltage. Therefore, the input can be mathematically expressed by: Q=(i1 t1+i2 t2+i3 t3 . . . +iₙ tₙ).

The ADC 102 operation starts with pre-charging the capacitor 108 to a reference voltage level Vref applied at port 132. The pre-charge is controlled by a signal pre-charge_en_n 134. The associated transistor 116, controlled by pre-charge_en_n 134, pre-charges the capacitor 108 through isolation transistor 114. During pre-charge, signal phase-control 144 is maintained at logic high, providing the pre-charge current to flow. The pre-charge phase is presented in the signal flow diagram in FIG. 1-D.

The ADC charge accumulation phase starts with pre-charge_en_n transitioning logic from low to high. In the charge accumulation phase, the output charge from the preceding multiplier block accumulates to the capacitor 108. Having the phase control signal 144 level at high enables the transistors 112 and 114 to allow the current to flow. In this way, the charges can accumulate in the capacitor 108. In this phase, both the transistors 112 and 114 are in an ON state. The charge accumulation phase ends with voltage developed across the capacitor 108, which is eventually converted to digital value in resolution phase.

During the charge accumulation phase, the voltage of node 106 shifts from the pre-charged level Vref to a voltage Vmac 172 within the stipulated time as shown in FIG. 1-D. To convert the Vmac voltage to a digital value, the node voltage is ramped with a constant slope back to the initial value Vref. The time to reach the voltage of node 106 from Vmac back to Vref is directly proportional to the Vmac. While node 106 is ramping towards Vref, an up counter is made to count up to measure the time.

The resolution phase starts when the phase control signal 144 makes a transition from logic high to logic low. As shown in FIG. 1-A, as the signal 144 goes low, it turns off the transistors 112 and 114. As a result, the capacitor top plate 106 is now floating and the bottom plate 110 is driven by ref_slope applied on port 142. Then, node 110 is ramped up with the external reference slope generated by the ADC control 104 of FIG. 1-B. As the button plate of the capacitor 108 is under a constant ramp, the top plate node 106 also follows the bottom plate ramp as node 106 is floating.

Node 106 of FIG. 1-A is connected to the high-impedance input node of a comparator 120. The comparator 120 monitors the ramp of 106 and generates an active low output when node 106 under constant ramp reaches back to the voltage level Vref 132, the initial pre-charged level. The point is marked as 164 in the signal flow FIG. 1-D.

While the signal phase control 144 initiates the ramp on node 106, it enables the counter, as shown in FIG. 1-D. That means the N-bit up counter 162 output starts counting up at each clock 158 edges once the resolution phase starts. At the comparator detection, the counter value at the N-Bit counter bus 148 is latched by the N-bit D-latch 128 and produced as ADC output 130, as shown in FIG. 1-A.

At the end of this resolution phase, the system resets. The reset includes different operations like, inter alia: pre-charge, reset of the counter, etc. Therefore, if, due to any unforeseen event, the node 106 ramp does not reach the target Vref 132 within the stipulated time defined by the resolution phase, the comparator does not trigger hence, the ADC output becomes undefined. The system design and tuning can ensure that node 106 returns to Vref for a given input range. However, if the input goes beyond the range, the Vmac of FIG. 1-D can have a significant differential with respect to Vref, which, while ramped, may not reach Vref within the stipulated time under the predefined constant ramp. The innovation implements “Overflow Safe” circuitry 122 to ensure the best ADC output for such out-of-range input rather than an undefined ADC output. For this purpose, an active low signal EOC_n generated by the controller at the end of the resolution phase. The EOC_n signal when interacting with circuit 122, produces a definite logic low to high transition on signal 123, which is necessary if missed due to the above-mentioned reasonings. In addition to the out-of-range protection circuit, circuitry 122 prevents spurious triggers by the comparator. It allows the comparator-generated trigger to pass only at the resolution phase. The example circuit of 122 is shown in FIG. 1-C.

The output active high step signal 123 of circuit 122 can be used to latch the counter data. However, signal 123 lacks a major requirement to interface to a synchronous system. The signal 123 is still asynchronous. The circuit system 124 synchronizes signal 123 with clock 146 and creates a pulse signal from the step signal. The synchronous pulse output 126 from circuit 124 is then used as a clock (clk) to the N-Bit D-Latch 128 to latch the N-Bit counter 148 data and produce an N-Bit ADC output of 130. The waveform of latching is demonstrated in FIG. 1-D.

The control system 104 for the ADC is described in FIG. 1-B. The control circuit 160 is implemented with a Finite State Machine (FSM) 160. FSM 160 receives an external clock 158 and generates all the digital control signals, such as pre-charge_en_n 134, phase control 144, EOC_n 140 and a gated clock 146. Pre-charge_en_n 134 is an active low signal that controls the pre-charge of node 106 to Vref. Phase control 144 is the signal responsible for starting and ending two main phases: charge accumulation phase and ADC resolution phase, as described in FIG. 1-D. The signal 144 also couples the reference slope 142 to the capacitor node 106 of FIG. 1-A. System 162, an N-bit up-counter, is another element of the control system 104. This counter 162 starts the counting in the resolution phase once it receives a high-to-low transition on phase control signal 144. System 104 also receives Vref 132 and bl_ref 134 from the preceding reference circuit. The bl_ref 134 is directly supplied to the ADC 102, and Vref is used inside the control system 104 and supplied to the ADC 102.

ADC control 104 employs a reference current source Iref 150, capacitor 152, transistor 156 and an amplifier 154. The arrangement consisting of Iref 150, capacitor 152 and transistor 156 generates the reference ramp at node 157 when the phase control signal 144 from the FSM 160 makes a transition from logic high to low, as it turns off the transistor 156 and causes the current Iref 150 to flow into the capacitor 152. The reference ramp at 157 is then buffered with the help of an amplifier 154 and transmitted to the ADC on the signal ref_slope 142. The signal flow diagram of the ref_slope 142 ramp is captured in FIG. 1-D. The ramp at 142 causes the bottom plate 110 of FIG. 1-A of the floating capacitor to ramp, and eventually, the top plate 106 also follows the ramp. Therefore, the ramp at node 106 is achieved by ramping up the bottom plate rather than charging the capacitor. The top plate of the capacitor 152 is connected to Vref 132, and the bottom plate is tied to the circuit ground in the charge accumulation phase and ramped up during the resolution phase to ensure the voltage swings across the capacitor 152 at the resolution phase is the same as the swing across capacitor 108 of ADC 102 in FIG. 1-A during the charge accumulation phase. A similar voltage swing across the two capacitors 152 and 108 of resolution and charge accumulation phase, respectively, cancels out error due to capacitor variation with voltage swing.

As shown in FIGS. 1-C, circuits 122 and 124 serve the purpose of making the system overflow-safe and synchronizing the comparator output with the clock 146. An example implementation of circuit 122 uses two control inputs: phase control 144 and EOC_n (end of conversion) 140, with comparator output as its input. The comparator output is gated with signal phase control 144, which allows the comparator active low output to pass only at the resolution phase. The comparator output and signal 144 are both active low. The active low pulse on EOC_n 140 ensures output 123 of circuit 122 makes a low-to-high transition even if the comparator output fails to trigger. As the EOC_n triggered 123 active high output in case of unbounded input, the ADC generates the best possible ADC output that is the maximum N-bit Counter output value. Therefore, the innovation implements the circuit with an active low EOC_n 140 pulse, which comes at the end of the resolution phase or at the end of the conversion where the counter reaches its maximum count, which can eventually be captured as ADC output 130 of FIG. 1-A.

As shown in FIGS. 1-A and 1-C with comparators 120 and circuit 122, the system can generate a well-defined trigger signal 123 when the 106 returns to the Vref 132 level or at the end of the conversion. However, this signal still is not up to the mark to latch the high-speed N-Bit counter signal 148 because the signal 123 is not synchronized with the clock. On top of that, to latch the counter, a pulse is required, where the 123 is a step signal. Therefore, the innovation implements circuit 124 of FIG. 1-A. Example details of the circuit are shown in FIG. 1-C. The asynchronous signal 123 is first synchronized with the help of Flip Flop 174. At this point, the output 178 of the flip flop 174 has yet to become a pulse. The output 178 is applied to the pulse generator comprised of delay chain 176, inverter 180 and an AND gate 182. The delay is tuned for the optimal pulse width for signal 126 to achieve optimum latching action in the following D-Latch 128.

FIG. 1-D depicts the signal flow diagram and elaborates on the phases of the ADC operation. FIG. 1-D describes the signal dependency as well. The operation starts with the prechare_en_n transits low to high when node 106 to Vref pre-charge is completed. As soon as the 134 goes high, the input charge starts to the capacitor 108. Hence, the node voltage 106 deviates from the Vref level and settles down to voltage Vmac 172 within a predefined time frame of charge accumulation phase 166. The phase control signal 144 is high in the charge accumulation phase, which enables the current through the transistors 112 and 114. The charge accumulation phase 166 ends, and the ADC resolution phase starts with the phase control signal 144, making a high-to-low transition. An operation in this phase is a constant ramp of node 106, shown in FIG. 1-D. The ramp of node 106 is achieved by the ramp on the net ref_slope 142. With the application of the ramp, node 106 crossed the Vref level at the point marked by the dotted circle 164. When node 106 crosses the Vref, net 126 makes a pulse to latch the N bit counter 148, producing the output 130. The toggle of 130 is shown in the FIG. 1-D. At the end of the conversion, the active low signal EOC_n 140 does toggle. At the end of the resolution phase, the pre-charge phase starts with pre-charge_en_n 134 toggles from high to low and phase control 144 toggles from low to high. As the control signal toggles to the required values in the pre-charge phase, ref_slope 134 falls back to voltage level “zero” and node 106 precharges back to Vref level.

FIG. 1-E shows an example of a multi-ADC system 172, according to some embodiments. The system can utilize a single control unit, 104, with multiple ADCs 102<*> connected to the control signal. The system applies the reference slope to the bottom plate 110 of the ADC capacitor 108 and ramps it up. This scheme facilitates the implementation of multiple ADCs with a single ref_slope generator. This is possible as the bottom plate is common and can be shortened together for all the ADC, unlike the top plate, which ends up having different potentials at the end of the charge accumulation phase. FIG. 1-E shows multiple instantiations of ADC 102<*>. The ADCs are represented by block diagrams with the most vital component capacitor 106, transistor 112 and the bottom plate 110 shown. The tapping of control signals from control block 104 is represented by black dots.

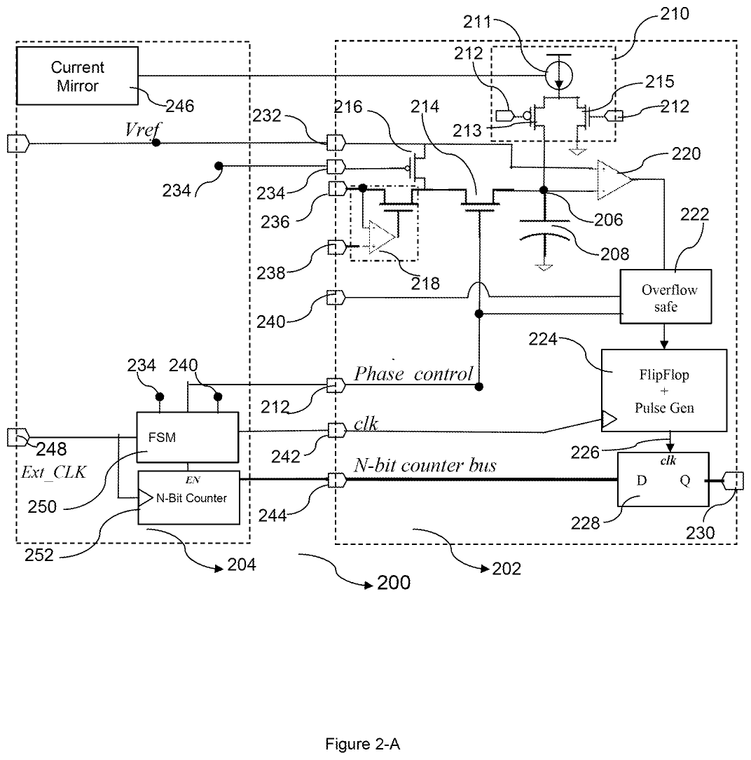

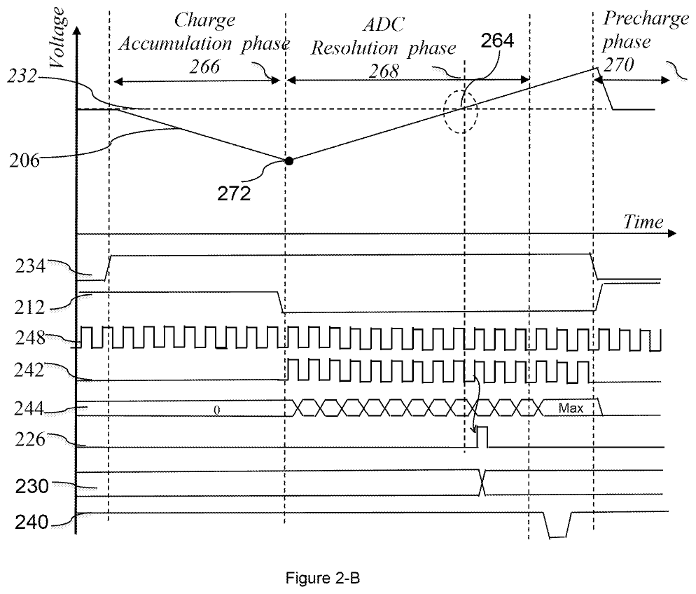

FIG. 2-A depicts system 200 with an alternate implementation of the ADC 202, hence control system 204. In contrast to FIG. 1-A, the system in FIG. 2-A implements a circuit side 210 to apply the reference slope on node 206 during the resolution phase. The ADC 202 implements sub-system 218, consisting of an opamp and a transistor that receive the charge input on port 236 and transfers it to capacitor 208. Transistor 216 performs the pre-charge of node 206 and is controlled by the input signal on pre-charge_en_n 234. Transistor 214 isolates the capacitor node 206 in the resolution phase and is controlled by phase control 212. The capacitor 208 is connected between 206 and the circuit ground. Circuit 210 has one current mirror secondary side 211 with the reference side 246 at control 204 and two enable transistors 213 and 215. Transistors 213 and 215 are controlled by signal phase control signal 212. It is noted that the reference ramp is required during the resolution phase only. However, the current source 210 cannot be turned off during the charge accumulation phase because it may need a significantly large settling time. Therefore, the current source using 210 is kept on, and the transistors 213 and 215 with a control signal 212 divert the current to the ground in the charge accumulation phase and route it to the capacitor 208 to perform a constant ramp at the resolution phase. Comparator 220 detects when the ramp on 206 reaches back to the Vref level. Circuit 222 helps to perform the proper operation while the input is out of the range. Next, circuit 224 synchronizes the signal with the clock and generates a pulse. The pulse output from system 224 is used to latch the counter output and produces 230 as the ADC output.

The control unit 204 generates all the necessary control signals with the help of FSM 250. The FSM receives an external clock 248 and generates a gated clock 242 for the ADC. The Clock 242 is gated to save power as the toggling required by the ADC 202 is only during the resolution phase, as shown in FIG. 2-B. Like clock 242, counter running is only required during the resolution phase. Therefore, the N-Bit up counter 252 is controlled by the enable signal from the FSM, which is enabled only at the onset of the resolution phase, as shown in FIG. 2-B. The control unit implements the current mirror reference side 246 as well.

FIG. 2-B depicts the signal flow diagram for the implementation of FIG. 2-A. The ADC conversion is divided into 3 phases: a charge accumulation phase 266, a resolution phase 268, and a pre-charge phase 270. The phases are controlled by signal pecharge_en_n 234 and phase control signal 212. The developed voltage during the charge accumulation phase is shown as point 272. During the resolution phase, the return to Vref is marked by the dotted circle 264. As the 206 returns to Vref at point 264, a synchronized pulse on signal 226 appears with the help of circuits 222 and 224 of FIG. 2-A at the immediate next clock 242 positive edge. The pulse on signal 226 is used to latch the N-Bit counter data 244 data and produce the ADC output 230. When the counter reaches the maximum value, the EOC_n 240 active low toggling appears at the end of the ADC conversion.

### CONCLUSION

Although the present embodiments have been described with reference to specific example embodiments, various modifications and changes can be made to these embodiments without departing from the broader spirit and scope of the various embodiments. For example, the various devices, modules, etc., described herein can be enabled and operated using hardware circuitry, firmware, software or any combination of hardware, firmware, and software (e.g., embodied in a machine-readable medium).

In addition, it can be appreciated that the various operations, processes, and methods disclosed herein can be embodied in a machine-readable medium and/or a machine-accessible medium compatible with a data processing system (e.g., a computer system), and can be performed in any order (e.g., including using means for achieving the various operations). Accordingly, the specification and drawings are to be regarded in an illustrative rather than a restrictive sense. In some embodiments, the machine-readable medium can be a non-transistor form of machine-readable medium.

What is claimed as new and desired to be protected by Letters Patent of the United States is:

1. An analog-to-digital converter (ADC) system comprising:
a complementary metal-oxide-semiconductor (CMOS) circuit configured to receive a charge as an input charge that is converted to a digital value;
a capacitor configured to store the input charge and develop a voltage across the capacitor that is proportional to the input charge;
a CMOS pre-charge circuit configured to pre-charge the capacitor to a reference voltage (Vref);
a top plate of the capacitor that is initially held to the Vref while a bottom plate is tied to a circuit ground or an alternative fixed voltage, wherein during a charge accumulation phase, a voltage across the capacitor starts with Vref and ends at a different value based on accumulated charge;
a CMOS voltage level comparator configured to monitor a capacitor ramp in the resolution phase and to detect when a capacitor ramp reaches a predefined voltage level;
a synchronizer circuit configured to synchronize an asynchronous output signal of the CMOS voltage level comparator with a clock;
a pulse generator configured to generate a pulse from a signal from the comparator followed by the synchronizer; and
a N-bit latch configured to latch the counter using the pulse from the pulse generator.

2. The ADC system of claim 1 further comprising:
a clamp circuit configured to hold a bit line to a fixed voltage when the bit line current is being accumulated in a sense capacitor.

3. The ADC system of claim 2, wherein the ADC system comprises a CMOS circuit that serves as an accumulator for the Multiply and Accumulator (MAC) system.

4. The ADC system of claim 3, wherein the voltage across the sense capacitor changes from a predetermined value based on the accumulated charge during the accumulation phase.

5. The ADC for MAC system of claim 4, wherein the accumulated voltage on sense capacitor is V=(1/C)I*T where C is the sense capacitance, I is the average bit line current, and T is the bit line charge accumulation time.

6. The ADC system of claim 1 which uses a CMOS transistor configured to connect the bottom plate of the capacitor to fixed voltage node or a ramped voltage node during a charge development phase and a resolution phase respectively.

7. The ADC system of claim 6 wherein, during the resolution phase a node of the top plate of the sense capacitor is ramped by floating the top plate and ramping the bottom plate to perform the resolution phase.

8. The ADC system of claim 6 wherein a node connecting to the bottom plate is common to a plurality of ADCs.

9. The ADC system of claim 1 which always keeps the bottom plate of the sense capacitor to a fixed voltage.

10. The ADC system of claim 9, wherein in the resolution phase, the top plate node of the sense capacitor is ramped by directly charging the sense capacitor with a predetermined constant current source to the top plate of the capacitor while holding the bottom plate to a predetermined fixed voltage.

11. The ADC system of claim 10, wherein the current source comprises a current mirror with a reference side that is placed in the ADC control unit.

12. An ADC system of claim 1 further comprising an ADC control system:
a voltage generator which generates a reference voltage Vref for sense capacitor precharge in an ADC; and also for sense capacitor voltage detection level of a comparator in the ADC;
a voltage generator which generates a bit line reference voltage bl-ref to hold the bit line at bit line reference voltage bl_ref during accumulation time of the bit line current in an ADC; and
a finite state machine which generates a plurality of timing and control signals for an ADC; and also generates a count to measure the time required to ramp the sense capacitor to a pre-determined voltage level in the ADC.

13. The ADC control system of claim 12 comprising a voltage ramp circuit which generates a voltage ramp to apply to the sense capacitor node during a resolution period of an ADC so as to measure the accumulated charge on the sense capacitor of the ADC.

14. The ADC system of claim 13 further comprising:
an ADC control unit configured to generate a reference ramp using a current source and an associated capacitor; wherein one plate of the capacitor is connected to the Vref, and another plate of capacitor is ramped up with a constant slope defined by ramp current source.

15. The ADC system of claim 12, wherein the reference ramp is buffered or amplified and then applied to the ADC system.

16. The ADC of MAC system of claim 12, wherein the count signals drive a plurality of ADCs.

17. The ADC of MAC system of claim 1, wherein the ADC generates a pulse that is used to latch the counter data generated by the control unit.

18. The ADC of MAC system of claim 12, wherein the sense capacitor is set effectively at the same value as the ramp generator capacitor so as to remove systematic errors between accumulation and resolution phase in ADC output’ caused by process variations in capacitors.
